(19) United States
(12) Patent Application Publication
(10) Pub. No.: US 2026/0142585 A1
(43) Pub. Date: May 21, 2026

(54) POWER CONVERSION APPARATUS

(71) Applicant: FUJI ELECTRIC CO., LTD., Kawasaki-shi (JP)

(72) Inventor: Yuhei SUZUKI, Suzuka-shi (JP)

(21) Appl. No.: 19/337,985

(22) Filed: Sep. 24, 2025

(30) Foreign Application Priority Data
Nov. 18, 2024 (JP) 2024-200786

(51) Int. Cl. H02M 7/00; H05K 7/20

(52) U.S. Cl. CPC H02M 7/003; H05K 7/20172; H05K 7/20918

(57) ABSTRACT

A power conversion apparatus according to this invention includes a power converter including a smoothing capacitor and a direct-current reactor; and an enclosure including a wind tunnel through which cooling air flows to cool the power converter, wherein the smoothing capacitor and the direct-current reactor are arranged in the wind tunnel such that positions of the smoothing capacitor and the direct-current reactor overlap with each other in a Z direction in which the cooling air flows.

### CROSS-REFERENCE TO RELATED APPLICATIONS

The present application claims priority of Japanese Patent Application No. JP2024-200786, power conversion apparatus, filed on Nov. 18, 2024, Yuhei Suzuki, and is hereby incorporated by reference.

### BACKGROUND OF THE INVENTION

### Field of the Invention

The present invention relates to a power conversion apparatus, and in particular to a power conversion apparatus including a smoothing capacitor and a direct-current reactor.

### Description of the Background Art

Frequency conversion units (power conversion apparatuses) including capacitor means and choke coil means are known in the art. Such a power conversion apparatus is disclosed in German Utility Model No. DE202012101290U1, for example.

The above German Utility Model No. DE202012101290U1 discloses a frequency conversion unit including control electronic means, capacitor means, choke coil means, fan means, and a cabinet. In the frequency conversion unit disclosed in the above German Utility Model No. DE202012101290U1, the capacitor means and the choke coil means are arranged inside the cabinet to be cooled by cooling airflows produced by the fan means. Also, in the frequency conversion unit disclosed in the above German Utility Model No. DE202012101290U1, the capacitor means and the choke coil means are aligned in a ventilation direction in which cooling air flows inside the cabinet.

### SUMMARY OF THE INVENTION

However, when the capacitor means and the choke coil means are aligned in the direction in which cooling air flows inside the cabinet as in the frequency conversion unit disclosed in the above German Utility Model No. DE202012101290U1, the dimension of the frequency conversion unit in the ventilation direction increases. For this reason, the frequency conversion unit may not be installed in a control panel having a small installation location, for example, in some cases. Accordingly, it is desirable to reduce the size in the ventilation direction even in frequency conversion units (power conversion apparatuses) including capacitor means (smoothing capacitors) and choke coil means (direct-current reactors).

The present invention is intended to solve the above problem, and one object of the present invention is to provide a power conversion apparatus capable of reducing its size in a ventilation direction while incorporating a smoothing capacitor and a direct-current reactor.

In order to attain the aforementioned object, a power conversion apparatus according to one aspect of the present invention includes a power converter including a smoothing capacitor and a direct-current reactor; and an enclosure including a wind tunnel through which cooling air flows to cool the power converter, wherein the smoothing capacitor and the direct-current reactor are arranged in the wind tunnel such that positions of the smoothing capacitor and the direct-current reactor overlap with each other in a ventilation direction in which the cooling air flows.

In the power conversion apparatus according to the one aspect of this invention, as discussed above, the smoothing capacitor and the direct-current reactor are arranged in the wind tunnel such that positions of the smoothing capacitor and the direct-current reactor overlap with each other in a ventilation direction in which the cooling air flows. Here, in a case where the positions of the smoothing capacitor and the direct-current reactor do not overlap with each other in the ventilation direction, the size of the wind tunnel in the ventilation direction is necessarily made larger than the sum of the size of the smoothing capacitor in the ventilation direction and the size of the direct-current reactor in the ventilation direction. In this case, the dimension of the power conversion apparatus including the wind tunnel in the ventilation direction increases. In contrast, according to the aforementioned configuration, the size of the wind tunnel in the ventilation direction can be reduced by overlapping the positions of the smoothing capacitor and the direct-current reactor with each other in the ventilation direction. Consequently, the size of the power conversion apparatus in the ventilation direction can be reduced even when the power conversion apparatus includes the smoothing capacitor and the direct-current reactor.

In the aforementioned power conversion apparatus according to the one aspect, it is preferable that the smoothing capacitor and the direct-current reactor are arranged such that the positions of the smoothing capacitor and the direct-current reactor do not overlap with each other as viewed in the ventilation direction. According to this configuration, the positions of the smoothing capacitor and the direct-current reactor can easily overlap with each other in the ventilation direction. In addition, because neither the smoothing capacitor nor the direct-current reactor obstructs cooling air that flows through the other in the wind tunnel, both the smoothing capacitor and the direct-current reactor can be efficiently cooled.

In this configuration, it is preferable that the power converter includes a semiconductor module; that a cooler in contact with the semiconductor module to cool the semiconductor module is further provided; and that the cooler is arranged such that a position of the cooler overlaps with the positions of the smoothing capacitor and the direct-current reactor as viewed in the ventilation direction. According to this configuration, not only heat generated from the semiconductor module, but also heat generated from the smoothing capacitor and the direct-current reactor can be cooled by using the cooler cooling the semiconductor module.

In the aforementioned power conversion apparatus that includes the semiconductor module, it is preferable that the smoothing capacitor is arranged to protrude from an exterior of the wind tunnel into an interior of the wind tunnel; and that the smoothing capacitor and the direct-current reactor are spaced away from each other in a direction in which the smoothing capacitor protrudes. Here, advantages will be discussed where a direction perpendicular to both the ventilation direction and the direction in which the smoothing capacitor protrudes is defined as a width direction. According to this configuration, the size of the power conversion apparatus in the width direction can be reduced dissimilar to a case where the smoothing capacitor and the direct-current reactor are spaced away from each other in the width direction. Consequently, the installation area of the power conversion apparatus can be reduced.

In the power conversion apparatus according to one of the above aspects, it is preferable that a partition plate arranged in the wind tunnel to partition a space in which the smoothing capacitor and the direct-current reactor face each other into spaces is further provided. According to this configuration, because the space where the smoothing capacitor and the direct-current reactor face each other is partitioned, the smoothing capacitor can be less affected by heat from the direct-current reactor, and vice versa.

In this configuration, it is preferable that the power converter includes a semiconductor module; that the direct-current reactor is configured to generate a larger amount of heat than the smoothing capacitor; and that the partition plate is configured to partition a portion of a space between the semiconductor module and the direct-current reactor as the space where the smoothing capacitor and the direct-current reactor face each other into the spaces. According to this configuration, the semiconductor module, which is susceptible to failure caused by heat, can be arranged in a space that is partitioned from the direct-current reactor, which generates a large amount of heat. Consequently, the semiconductor module is less affected by heat radiated from the direct-current reactor.

In the aforementioned power conversion apparatus that includes the partition plate partitioning a space where the smoothing capacitor and the direct-current reactor face each other, it is preferable that a fan arranged in the wind tunnel to produce the cooling air is further provided; and that the fan is configured to produce the cooling air both in a capacitor-side space where the smoothing capacitor is placed as one of the spaces partitioned by the partition plate and a reactor-side space where the direct-current reactor is placed as another of the spaces partitioned by the partition plate. According to this configuration, because the fan can produce cooling air in both the capacitor-side space and the reactor-side space, both the smoothing capacitor and the direct-current reactor can be cooled. In addition, because the capacitor-side space and the reactor-side space are partitioned, it is possible to prevent the cooling air that flows through one of the spaces from flowing into the other space.

In the aforementioned power conversion apparatus that includes the partition plate partitioning a space where the smoothing capacitor and the direct-current reactor face each other, it is preferable that the partition plate is formed of an electrically insulating resin. According to this configuration, because the partition plate is formed of a resin with lower thermal conductivity than a metal, for example, the smoothing capacitor is even less affected by heat generated from the direct-current reactor, and vice versa. In addition, the electrically insulating partition plate can prevent a short circuit between the smoothing capacitor and the direct-current reactor if they are too close to each other.

In the aforementioned power conversion apparatus according to the one aspect, it is preferable that the power converter includes a semiconductor module; that a cooler arranged in the wind tunnel to be in contact with the semiconductor module to cool the semiconductor module, and a fan arranged in the wind tunnel to produce the cooling air are further provided; and that the fan is arranged in proximity to the cooler on a side opposite to the smoothing capacitor and the direct-current reactor, which are arranged such that the positions of the smoothing capacitor and the direct-current reactor overlap with each other in the ventilation direction, with respect to the cooler. According to this configuration, the fan arranged in proximity to the cooler can effectively blow cooling air to the cooler, which necessarily serves to cool the semiconductor module.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a perspective view showing a power conversion apparatus according to one embodiment of the present invention.

FIG. 2 is a circuit diagram showing electrical connections in the power conversion apparatus according to the one embodiment of the present invention.

FIG. 3 is a side view of the power conversion apparatus according to the one embodiment of the present invention.

FIG. 4 is a cross-sectional view of the power conversion apparatus taken along a line IV-IV in FIG. 3.

FIG. 5 is a side view of the power conversion apparatus according to a modified example of the one embodiment of the present invention.

FIG. 6 is a cross-sectional view of the power conversion apparatus taken along a line VI-VI in FIG. 5.

### DESCRIPTION OF THE PREFERRED EMBODIMENT

The following description will describe one embodiment embodying the present invention with reference to the drawings.

### Configuration of Power Conversion Apparatus

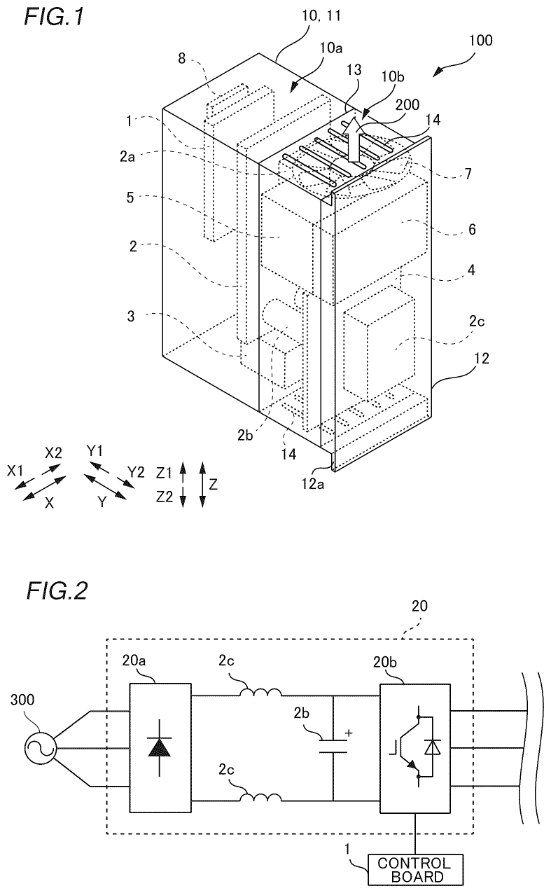

The following description describes a configuration of a power conversion apparatus 100 according to this embodiment with reference to FIGS. 1 and 2.

As shown in FIG. 1, the power conversion apparatus 100 includes a control board 1, a main circuit board 2 on which a semiconductor module 2a and a smoothing capacitor 2b are arranged, direct-current reactors 2c, a terminal base 3, a partition plate 4, a heat sink 5, a support 6, a fan 7, a control panel 8, and an enclosure 10 accommodating them. The power conversion apparatus 100 is a so-called inverter apparatus arranged in a console, for example. Here, the heat sink 5 is an example of a “cooler” in the claims.

In this specification, a ventilation direction in which the fan 7 produces cooling air is defined as a Z direction (vertical direction). Also, an upward vertical direction along the Z axis is defined as a Z1 direction, and a downward direction along the Z axis is defined as a Z2 direction. Also, a direction perpendicular to the Z direction is defined as an X direction. One direction along the X axis is defined as an X1 direction, and the other direction along the X axis is defined as an X2 direction. In addition, another direction perpendicular to the X direction is defined as a Y direction. One direction along the Y axis is defined as a Y1 direction, and the other direction along the Y axis is defined as a Y2 direction. Here, the Z direction is an example of a “ventilation direction” in the claims, and the Y direction is an example of an “extension direction of the smoothing capacitor” in the claims.

The control board 1 in FIG. 1 is a board controlling a power converter 20 (see FIG. 2) of the power conversion apparatus 100. The control board 1 is connected to the main circuit board 2 via wiring (not shown). Also, the control board 1 is configured to control activation of a plurality of switching elements (not shown) that is included in the semiconductor module 2a of the power converter 20, for example.

The control board 1 includes a CPU (Central Processing Unit) as a processor, a ROM (Read Only Memory), a RAM (Random Access Memory) and the like. The control board 1 is configured to be able to transmit/receive signals to/from the control panel 8, which will be described later, using communication lines (not shown). Accordingly, the control board 1 acquires information input via the control panel 8, controls operation of the power converter 20 (see FIG. 2), and displays a status of power conversion operation performed by the power converter 20 on the control panel 8.

The main circuit board 2 is a power conversion board to which a plurality of circuit elements including the semiconductor module 2a, the smoothing capacitor 2b, and the direct-current reactors 2c is connected. Here, the semiconductor module 2a and the smoothing capacitor 2b are mounted on the main circuit board 2, and the direct-current reactors 2c are connected to the main circuit board 2 via a bus bar or the like (not shown).

The main circuit board 2 includes the power converter 20 shown in FIG. 2. The power converter 20 includes a rectifier circuit 20a, an inverter circuit 20b, the smoothing capacitor 2b, and the direct-current reactors 2c. The power converter 20 converts alternate-current power supplied from commercial power 300 into direct-current power by using the rectifier circuit 20a, the smoothing capacitor 2b, and the direct-current reactors 2c. Also, the power converter 20 changes the generated direct-current power to alternate-current power and outputs the changed alternate-current power with a changed frequency, a changed voltage, and the like to a load or the like (not shown) by using the inverter circuit 20b.

The semiconductor module 2a is a module that accommodates switching elements (not shown) inside a plastic enclosure. The switching elements included in the semiconductor module 2a are transistors, for example. The enclosure of the semiconductor module 2a is fixed to the heat sink 5, which is arranged on the Y2-direction side, by fasteners (not shown).

For example, an electrolytic capacitor is used as the smoothing capacitor 2b. Also, as shown in FIG. 2, the smoothing capacitor 2b is used to smooth power rectified by the semiconductor module 2a. Accordingly, a current that flows through the smoothing capacitor 2b generates heat. Also, the smoothing capacitor 2b is mounted on the main circuit board 2 and extends in the Y2 direction from the main circuit board to be in a wind tunnel 10b of the enclosure 10. The arrangement of the smoothing capacitor 2b will be described in detail later.

The direct-current reactors 2c are so-called coils. Also, as shown in FIG. 2, the direct-current reactors 2c are used to smooth power rectified by the rectifier circuit 20a. Also, the direct-current reactors 2c are used to reduce harmonic current noise from the inverter circuit 20b side toward the rectifier circuit 20a side. Also, currents that flow through the direct-current reactors 2c generates heat. Here, in this embodiment, the amount of heat generated by the direct-current reactors 2c is greater than that of the smoothing capacitor 2b. In addition, because the direct-current reactors 2c are relatively heavy, they are not mounted on the main circuit board 2 but are attached to a metal base 12 of the enclosure 10, which will be described later and arranged in the wind tunnel 10b. The arrangement of the direct-current reactors 2c will be described in detail later.

The terminal base 3 is connected to electrical wiring drawn from a power distribution board and the like (not shown), and wiring connected to the main circuit board 2. The terminal base 3 is provided with fastenings or the like that fix ends of various wires to prevent detachment of the various wires.

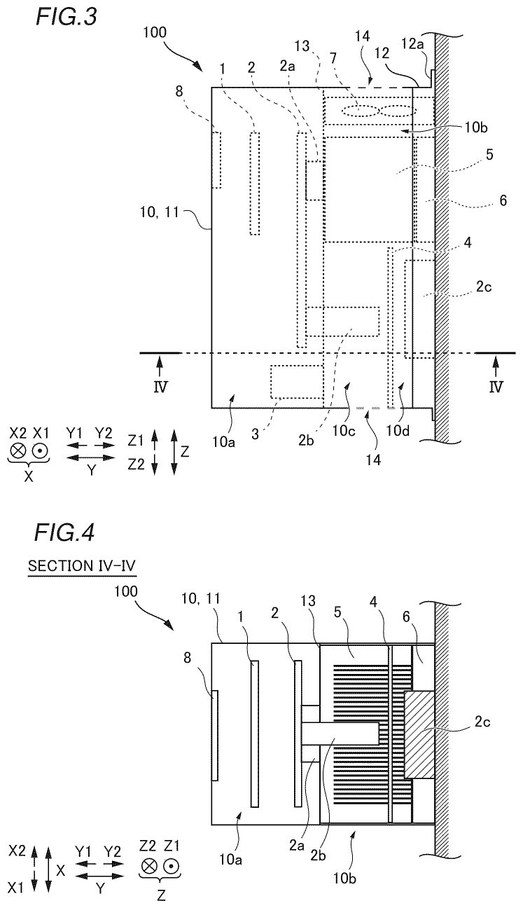

The partition plate 4 is configured to separate the wind tunnel 10b into a capacitor-side space 10c (see FIG. 3) and a reactor-side space 10d (see FIG. 3). The partition plate 4 is formed of a resin with relatively high heat resistance and dielectric strength, such as PPS (Poly Phenylene Sulfide) resin, for example. The arrangement of the partition plate 4 will be described in detail later.

The heat sink 5 includes a plurality of heat dissipating fins. The heat sink 5 is formed of a metal with relatively high thermal conductivity, such as aluminum, for example. The heat sink 5 is configured to be in contact with a surface of the enclosure of the semiconductor module 2a to absorb heat generated from the semiconductor module 2a and to dissipate the heat to the outside via air or the support 6. The heat sink 5 is arranged in the wind tunnel 10b of the enclosure 10. The arrangement of the heat sink 5 will be described in detail later.

The support 6 is arranged on the Z2-direction side of the heat sink 5. The support 6 is formed of a metal with relatively high thermal conductivity, such as aluminum, for example. The support 6 fills a gap between a Y2-directional surface of the heat sink 5 and the metal base 12 of the enclosure 10 to prevent cooling air flowing through the wind tunnel 10b from flowing through the gap so as to gather the cooling airflow toward the heat sink 5. Also, the support 6 is fixed to the metal base 12 of the enclosure 10.

The fan 7 is arranged in the wind tunnel 10b of the enclosure 10. The rotation axis of the fan 7 extends in the Z direction to pass air 200 from the Z2 side toward the Z1 side. In other words, the fan 7 cools the smoothing capacitor 2b, the direct-current reactors 2c and the heat sink 5, which are arranged in the wind tunnel 10b, by producing a flow of air 200 in the wind tunnel 10b. That is, air 200 produced by the fan 7 serves as cooling air in the wind tunnel 10b.

The control panel 8 is provided to receive command values manually input to the power conversion apparatus 100 from an operator or similar personnel. The control panel 8 is connected to the control board 1 via wiring or the like (not shown), and transmits information input from the operator similar personnel. The control panel 8 includes a display, such as a liquid crystal display, and displays the status of the power conversion apparatus 100. The control panel 8 includes a touch panel display, for example.

The enclosure 10 includes a resin cover 11 and the metal base 12. Also, the resin cover 11 includes a space partition plate 13 and ventilation apertures 14. The resin cover 11 is formed of a PPS resin, for example. The metal base 12 includes attachments 12a for attachment to a wall in the control cabinet in which the power conversion apparatus 100 is installed. The metal base 12 is formed of a relatively lightweight metal such as aluminum.

The space partition plate 13 is arranged inside the resin cover 11 to separate the interior of the enclosure 10 into two spaces. Here, among the spaces separated by the space partition plate 13, the space on the Y1-direction side is referred to as an airtight space 10a, and the space on the Y2-direction side is referred to as the wind tunnel 10b. The airtight space 10a accommodates the control board 1, the main circuit board 2, the semiconductor module 2a, a part of the smoothing capacitor 2b, the terminal base 3, and the control panel 8. Also, the wind tunnel 10b accommodates the other part of the smoothing capacitor 2b, the direct-current reactors 2c, the partition plate 4, the heat sink 5, the support 6, and the fan 7. The airtight space 10a is separated from the wind tunnel 10b by the space partition plate 13 to prevent the cooling air produced by the fan 7 from flowing into the airtight space.

The space partition plate 13 is formed of a relatively lightweight metal such as aluminum, for example. The space partition plate 13 has an opening (not shown) through which the smoothing capacitor 2b passes. Accordingly, the smoothing capacitor 2b is arranged to extend from the airtight space 10a into the wind tunnel 10b. Also, the space partition plate 13 has an opening (not shown) through which the semiconductor module 2a is attached to the heat sink 5. Here, the space partition plate 13 is arranged to be in contact with the Y1-directional surface of the heat sink 5.

The ventilation apertures 14 are formed on the Y2-direction side of each of the Z1-directional and Z2 directional surfaces of the resin cover 11. The ventilation apertures 14 have slit shapes, for example, and are configured to draw outside air into the interior of the wind tunnel 10b by the fan 7 and to discharge air 200, which is warmed when passing through the wind tunnel 10b.

### Arrangement Inside Wind Tunnel

The detailed arrangement inside the wind tunnel 10b is now described with reference to FIGS. 3 and 4.

As shown in FIG. 3, the smoothing capacitor 2b and the direct-current reactors 2c are arranged in the wind tunnel 10b such that their positions overlap with each other in the Z direction as the ventilation direction in which cooling air flows. Here, the smoothing capacitor 2b is arranged to protrude in the Y direction from the airtight space 10a, which is the exterior of the wind tunnel 10b, into the interior of the wind tunnel 10b.

Also, the space of the wind tunnel 10b in which the smoothing capacitor 2b and the direct-current reactor 2c face each other is partitioned by the partition plate 4 to be separated into the capacitor-side space 10c and the reactor-side space 10d. The smoothing capacitor 2b is placed in the capacitor-side space 10c, and the direct-current reactor 2c is placed in the reactor-side space 10d. The smoothing capacitor 2b and the direct-current reactors 2c are spaced away from each other in the Y direction in which the smoothing capacitor 2b protrudes. Accordingly, as shown in FIG. 4, the smoothing capacitor 2b and the direct-current reactors 2c are arranged such that their positions do not overlap with each other as viewed in the Z direction.

As shown in FIG. 3, both the capacitor-side space 10c and the reactor-side space 10d are connected to the ventilation apertures 14 of the enclosure 10 so that cooling air can flow into the spaces. Here, in this embodiment, because the amount of heat generated from the direct-current reactor 2c is greater than that of the smoothing capacitor 2b, the temperature in the reactor-side space 10d will be higher than the temperature in the capacitor-side space 10c.

Also, the heat sink 5 and the support 6 are arranged on the Z1-direction side with respect to the capacitor-side space 10c and the reactor-side space 10d. The heat sink 5 is arranged such that its position overlaps with the positions of the smoothing capacitor 2b and the direct-current reactors 2c as viewed in the Z direction. As shown in FIG. 4, the heat sink 5 has fins through which air 200 flows in the Z direction. The heat sink 5 and the support 6 are arranged to occupy the entire width of the wind tunnel 10b in the X direction. In other words, the wind tunnel 10b is configured such that all cooling air passing through it flows through the heat sink 5. Consequently, cooling air that passes through the capacitor-side space 10c and cooling air that passes through the reactor-side space 10d are cooled by the heat sink 5.

Here, because the temperature of the reactor-side space 10d is higher than that of the capacitor-side space 10c, the temperature of cooling air that flows on the Y1-direction side of the heat sink 5 is lower than that of cooling air that flows on the Y2-direction side of the heat sink 5. As a result, cooling air that has a relatively low temperature flows in proximity to a part of the heat sink 5 that is in contact with the semiconductor module 2a. In addition, because the partition plate 4 partitions a portion of a space between the semiconductor module 2a and the direct-current reactors 2c, the semiconductor module 2a is less affected by heat from the direct-current reactors 2c.

Also, the fan 7 is arranged in proximity to the heat sink 5 on a side opposite to the smoothing capacitor 2b and the direct-current reactors 2c, which are arranged such that their positions overlap with each other in the Z-direction, with respect to the heat sink 5. The fan 7 produces cooling air in both the capacitor-side space 10c and the reactor-side space 10d, which are separated by the partition plate 4. The cooling air produced by the fan 7 flows from the Z2-direction side toward the Z1-direction side.

### Advantages of the Embodiment

Advantages of this embodiment are now discussed.

In the power conversion apparatus 100 according to this embodiment includes the power converter 20 including the smoothing capacitor 2b and the direct-current reactors 2c; and the enclosure 10 including the wind tunnel 10b through which cooling air flows to cool the power converter 20, wherein the smoothing capacitor 2b and the direct-current reactors 2c are arranged in the wind tunnel 10b such that positions of the smoothing capacitor and the direct-current reactors overlap with each other in the Z direction in which the cooling air flows. Here, in a case where the positions of the smoothing capacitor 2b and the direct-current reactors 2c do not overlap with each other in the Z direction, the size of the wind tunnel 10b in the Z direction is necessarily dimensioned to be larger than the sum of the size of the smoothing capacitor 2b in the Z direction and the size of a set of the direct-current reactors 2c in the Z direction. In this case, the dimension of the power conversion apparatus 100 including the wind tunnel 10b in the Z direction increases. In contrast, according to the configuration of this embodiment, the size of the wind tunnel 10b in the Z direction can be reduced by overlapping the positions of the smoothing capacitor 2b and the direct-current reactors 2c with each other in the Z direction. Consequently, the size of the power conversion apparatus 100 in the Z direction can be reduced even when the power conversion apparatus includes the smoothing capacitor 2b and the direct-current reactors 2c.

Here, in this embodiment, the smoothing capacitor 2b and the direct-current reactors 2c are arranged such that their positions do not overlap with each other as viewed in the Z direction. According to this configuration, the positions of the smoothing capacitor 2b and the direct-current reactors 2c can easily overlap with each other in the Z direction. In addition, because neither the smoothing capacitor 2b nor the direct-current reactors 2c obstructs cooling air that flows through the other in the wind tunnel 10b, both the smoothing capacitor 2b and the direct-current reactors 2c can be efficiently cooled.

Also, in this embodiment, the power converter 20 includes the semiconductor module 2a; the heat sink 5 in contact with the semiconductor module 2a to cool the semiconductor module 2a is further provided; and the heat sink 5 is arranged such that its position overlaps with the positions of the smoothing capacitor 2b and the direct-current reactors 2c as viewed in the Z direction. Accordingly, not only heat generated from the semiconductor module 2a, but also heat generated from the smoothing capacitor 2b and the direct-current reactors 2c can be cooled by using the heat sink 5 cooling the semiconductor module 2a.

Also, in this embodiment, the smoothing capacitor 2b is arranged to protrude from the exterior of the wind tunnel 10b into the interior of the wind tunnel 10b, and the smoothing capacitor 2b and the direct-current reactors 2c are spaced away from each other in the Y direction in which the smoothing capacitor 2b protrudes. Accordingly, the size of the power conversion apparatus 100 in the X direction can be reduced dissimilar to a case where the smoothing capacitor 2b and the direct-current reactors 2c are spaced away from each other in the X direction. Consequently, the installation area of the power conversion apparatus 100 can be reduced.

Also, in this embodiment, the partition plate 4 arranged in the wind tunnel 10b to partition a space where the smoothing capacitor 2b and the direct-current reactors 2c face each other is further provided. Accordingly, because the space where the smoothing capacitor 2b and the direct-current reactors 2c face each other is partitioned, the smoothing capacitor can be less affected by heat from the direct-current reactors, and vice versa.

Also, in this embodiment, the semiconductor module 2a is provided; the direct-current reactors 2c are configured to generate a larger amount of heat than the smoothing capacitor 2b; and the partition plate 4 is configured to partition a portion of a space between the semiconductor module 2a and the direct-current reactors 2c. Accordingly, the semiconductor module 2a, which is susceptible to failure caused by heat, can be arranged in the space that is partitioned from the direct-current reactors 2c, which generate a large amount of heat. Consequently, the semiconductor module 2a is less affected by heat radiated from the direct-current reactors 2c.

Also, in this embodiment, the fan 7 arranged in the wind tunnel 10b to produce the cooling air is further provided; and the fan 7 is configured to produce the cooling air both in the capacitor-side space 10c where the smoothing capacitor 2b is placed as one of the spaces partitioned by the partition plate 4 and the reactor-side space 10d where the direct-current reactors 2c are placed as one of the spaces partitioned by the partition plate 4. Accordingly, because the fan 7 can produce cooling air in both the capacitor-side space 10c and the reactor-side space 10d, both the smoothing capacitor 2b and the direct-current reactors 2c can be cooled. In addition, because the capacitor-side space 10c and the reactor-side space 10d are partitioned, it is possible to prevent the cooling air that flows through one of the spaces from flowing into the other space.

Also, in this embodiment, the partition plate 4 is formed of an electrically insulating resin. Accordingly, because the partition plate 4 is formed of a resin with lower thermal conductivity than a metal, for example, the smoothing capacitor 2b is even less affected by heat generated from the direct-current reactors 2c, and vice versa. In addition, the partition plate 4 can prevent a short circuit between the smoothing capacitor 2b and the direct-current reactors 2c if they are too close to each other.

Also, in this embodiment, the power converter 20 includes the semiconductor module 2a; the heat sink 5 arranged in the wind tunnel 10b to be in contact with the semiconductor module 2a to cool the semiconductor module 2a, and the fan 7 arranged in the wind tunnel to produce the cooling air are further provided; and the fan 7 is arranged in proximity to the heat sink 5 on a side opposite to the smoothing capacitor 2b and the direct-current reactors 2c, which are arranged such that their positions overlap with each other in the Z direction, with respect to the heat sink 5. Accordingly, the fan 7 arranged in proximity to the heat sink 5 can effectively be blow cooling air to the heat sink 5, which necessarily serves to cool the semiconductor module 2a, which is a heat-generating component.

### Modified Embodiments

Note that the embodiment disclosed this time must be considered as illustrative in all points and not restrictive. The scope of the present invention is not shown by the above description of the embodiments but is limited by the scope of claims for patent, and all modifications (modified embodiments) within the meaning and scope equivalent to the scope of claims for patent are further included.

For example, while the example in which the smoothing capacitor 2b and the direct-current reactors 2c are arranged such that their positions do not overlap with each other as viewed in the Z direction has been shown in the aforementioned embodiment, the present invention is not limited to this. In the present invention, provided that the smoothing capacitor 2b and the direct-current reactors 2c are arranged such that their positions do not overlap with each other in the Z direction, the smoothing capacitor 2b and the direct-current reactors 2c may be arranged such that their positions overlap with each other as viewed in the Z direction.

Also, while the example in which the power converter 20 includes the semiconductor module 2a, the power conversion apparatus 100 further includes the heat sink 5 in contact with the semiconductor module 2a to cool the semiconductor module 2a, and the heat sink 5 is arranged such that its position overlaps with the positions of the smoothing capacitor 2b and the direct-current reactors 2c as viewed in the Z direction has been shown in the aforementioned embodiment, the present invention is not limited to this. In the present invention, the heat sink 5 may be arranged such that its position does not overlap with the positions of the smoothing capacitor 2b and the direct-current reactors 2c as viewed in the Z direction. In this case, the heat sink 5 may be arranged such that its position overlaps only with the position of the smoothing capacitor 2b as viewed in the Z direction, for example.

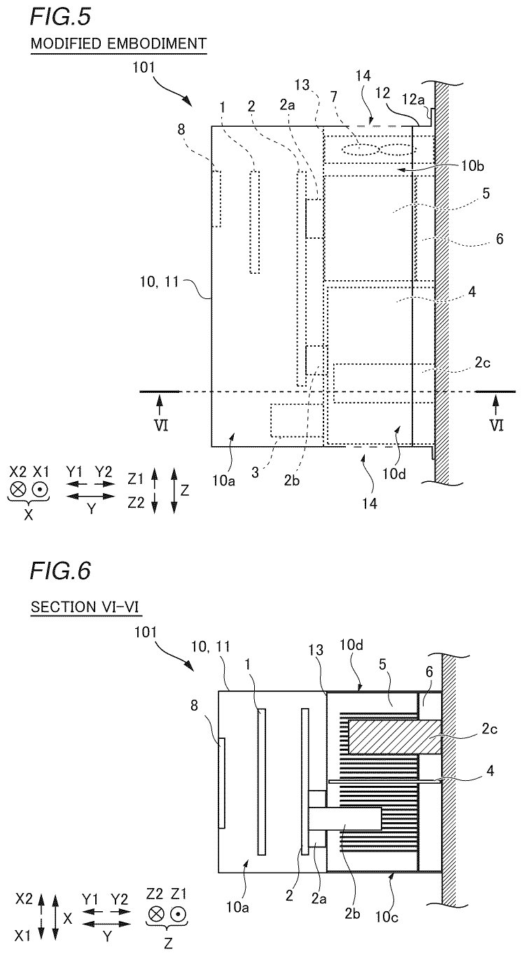

Also, while the example in which the smoothing capacitor 2b is arranged to protrude from the exterior of the wind tunnel 10b into the interior of the wind tunnel 10b, and the smoothing capacitor 2b and the direct-current reactors 2c are spaced away from each other in the Y direction in which the smoothing capacitor 2b protrudes has been shown in the aforementioned embodiment, the present invention is not limited to this. In the present invention, the smoothing capacitor 2b and the direct-current reactors 2c may be spaced away from each other in the X direction, for example, as in a modified embodiment shown in FIGS. 5 and 6. According to this arrangement, it is possible to reduce the thickness of the power conversion apparatus 100 in the X direction.

Also, while the example in which the partition plate 4 arranged in the wind tunnel 10b to partition a space in which the smoothing capacitor 2b and the direct-current reactors 2c face each other into spaces is provided has been shown in the aforementioned embodiment, the present invention is not limited to this. In the present invention, any member capable of partitioning the smoothing capacitor 2b from the direct-current reactors 2c may be used, such as a partitioning block. Alternatively, the partition plate 4 may not be provided.

Also, while the example in which the semiconductor module 2a is provided, the direct-current reactors 2c are configured to generate a larger amount of heat than the smoothing capacitor 2b, and the partition plate 4 is configured to partition a portion of a space between the semiconductor module 2a and the direct-current reactors 2c has been shown in the aforementioned embodiment, the present invention is not limited to this. In the present invention, the direct-current reactors 2c may generate approximately the same amount of heat as the smoothing capacitor 2b. In addition, the partition plate 4 may be configured to partition the entire space between the semiconductor module 2a and the direct-current reactors 2c.

Also, while the example in which the fan 7 arranged in the wind tunnel 10b to produce the cooling air is further provided, and the fan 7 is configured to produce the cooling air both in the capacitor-side space 10c where the smoothing capacitor 2b is placed as one of the spaces partitioned by the partition plate 4 and the reactor-side space 10d where the direct-current reactors 2c are placed as the other of the spaces partitioned by the partition plate 4 has been shown in the aforementioned embodiment, the present invention is not limited to this. In the present invention, the fan 7 may be arranged outside the wind tunnel 10b. Here, cooling air may be produced in one of the two spaces; the capacitor-side space 10c or the reactor-side space 10d.

Also, while the example in which the partition plate 4 is formed of an electrically insulating resin has been shown in the aforementioned embodiment, the present invention is not limited to this. In the present invention, the partition plate 4 may be formed of electrically insulating paper or the like, or may be formed of metal provided that electrical insulation between the smoothing capacitor 2b and the direct-current reactors 2c is ensured.

Also, while the example in which the power converter 20 includes a semiconductor module 2a, the heat sink 5 arranged in the wind tunnel 10b to be in contact with the semiconductor module 2a to cool the semiconductor module 2a and the fan 7 arranged in the wind tunnel to produce the cooling air are further provided, and the fan 7 is arranged in proximity to the heat sink 5 on a side opposite to the smoothing capacitor 2b and the direct-current reactors 2c, which are arranged such that their positions overlap with each other in the Z direction, with respect to the heat sink 5 has been shown in the aforementioned embodiment, the present invention is not limited to this. In the present invention, the fan 7 may be arranged at any position provided that cooling air can be produced in the wind tunnel 10b. For example, the fan 7 may be arranged in proximity to the smoothing capacitor 2b and the direct-current reactors 2c in the wind tunnel 10b.

Also, while the example in which the support 6 is formed of a metal with relatively high thermal conductivity, such as aluminum, has been shown in the aforementioned embodiment, the present invention is not limited to this. In the present invention, the support 6 may be any component capable of filling a space between the heat sink 5 and the Y1-directional surface of the metal base 12, such as a ceramic gap filler with high thermal conductivity.

Also, while the example in which the wind tunnel 10b accommodates the smoothing capacitor 2b, the direct-current reactors 2c, the heat sink 5 and the support 6 has been shown in the aforementioned embodiment, the present invention is not limited to this. In the present invention, the support 6 may not be arranged in the wind tunnel 10b, or another component may be arranged in the wind tunnel, for example.

Also, while the example in which the enclosure 10 includes the airtight space 10a and the wind tunnel 10b has been shown in the aforementioned embodiment, the present invention is not limited to this. In the present invention, for example, the enclosure may have a non-airtight space arranged adjacent to the wind tunnel 10b to accommodate the main circuit board 2 and the like, alternatively the wind tunnel 10b may be configured to allow cooling air to every part of the enclosure 10.

Also, while the example in which the power conversion apparatus 100 is an inverter apparatus has been shown in the aforementioned embodiment, the present invention is not limited to this. In the present invention, for example, the power conversion apparatus 100 may be a converter apparatus performing AC/DC conversion.

Also, while the example in which cooling air produced by the fan 7 flows from the Z2-direction side toward the Z1-direction side has been shown in the aforementioned embodiment, the present invention is not limited to this. In the present invention, the fan 7 may be configured to flow cooling air from the Z1-direction side toward the Z2-direction side.

What is claimed is:

1. A power conversion apparatus comprising:
a power converter including a smoothing capacitor and a direct-current reactor; and
an enclosure including a wind tunnel through which cooling air flows to cool the power converter, wherein
the smoothing capacitor and the direct-current reactor are arranged in the wind tunnel such that positions of the smoothing capacitor and the direct-current reactor overlap with each other in a ventilation direction in which the cooling air flows.

2. The power conversion apparatus according to claim 1, wherein the smoothing capacitor and the direct-current reactor are arranged such that the positions of the smoothing capacitor and the direct-current reactor do not overlap with each other as viewed in the ventilation direction.

3. The power conversion apparatus according to claim 2, wherein
the power converter includes a semiconductor module;
the apparatus further comprises a cooler in contact with the semiconductor module to cool the semiconductor module; and
the cooler is arranged such that a position of the cooler overlaps with the positions of the smoothing capacitor and the direct-current reactor as viewed in the ventilation direction.

4. The power conversion apparatus according to claim 3, wherein
the smoothing capacitor is arranged to protrude from an exterior of the wind tunnel into an interior of the wind tunnel; and
the smoothing capacitor and the direct-current reactor are spaced away from each other in a direction in which the smoothing capacitor protrudes.

5. The power conversion apparatus according to claim 1, further comprising a partition plate arranged in the wind tunnel to partition a space where the smoothing capacitor and the direct-current reactor face each other.

6. The power conversion apparatus according to claim 5, wherein
the power converter includes a semiconductor module;
the direct-current reactor is configured to generate a larger amount of heat than the smoothing capacitor; and
the partition plate is configured to partition a portion of a space between the semiconductor module and the direct-current reactor.

7. The power conversion apparatus according to claim 5, further comprising a fan arranged in the wind tunnel to produce the cooling air, wherein
the fan is configured to produce the cooling air both in a capacitor-side space where the smoothing capacitor is placed among the spaces partitioned by the partition plate and a reactor-side space where the direct-current reactor is placed among the spaces partitioned by the partition plate.

8. The power conversion apparatus according to claim 5, wherein the partition plate is formed of an electrically insulating resin.

9. The power conversion apparatus according to claim 1, wherein
the power converter includes a semiconductor module;
the apparatus further comprises a cooler arranged in the wind tunnel to be in contact with the semiconductor module to cool the semiconductor module, and a fan arranged in the wind tunnel to produce the cooling air; and
the fan is arranged in proximity to the cooler on a side opposite to the smoothing capacitor and the direct-current reactor, which are arranged such that the positions of the smoothing capacitor and the direct-current reactor overlap with each other in the ventilation direction, with respect to the cooler.
